(19) United States
(12) Patent Application Publication
(10) Pub. No.: US 2013/0049800 A1
(43) Pub. Date: Feb. 28, 2013

(54) SUB-THRESHOLD VOLTAGE CIRCUIT OF MULTI-CHANNEL LENGTH

(71) Applicants: JINN-SHYAN WANG, CHIAYI CITY (TW); CHUNG-HAN HSIEH, KAOHSIUNG COUNTY (TW); KENG-JUI CHANG, KAOHSIUNG CITY (TW)

(72) Inventors: JINN-SHYAN WANG, CHIAYI CITY (TW); CHUNG-HAN HSIEH, KAOHSIUNG COUNTY (TW); KENG-JUI CHANG, KAOHSIUNG CITY (TW)

(21) Appl. No.: 13/218,232

(22) Filed: Aug. 25, 2011

(51) Int. Cl. H03K 19/003

(52) U.S. Cl. 326/34

(57) ABSTRACT

A sub-threshold voltage circuit of multi-channel length includes a plurality of logic gates, which are electrically connected with one another according to a predetermined manner and composed of a plurality of PMOS transistors and a plurality of NMOS transistors. The logic gates form a plurality of signal paths defining at least one key signal path and a plurality of general signal paths respectively. The channel lengths of the logic gates located on the general signal paths each are the minimum channel length of the manufacturing process of the transistor. The logic gate located on the at least one key signal path is an RSCE PMOS or NMOS transistor, the channel length of which is larger than the minimum channel length of the manufacturing process of the transistor to define a maximum channel length. Thus, the performance is enhanced, leakage current is less, and the circuit area keeps proper in degree.

### BACKGROUND OF THE INVENTION

1. Field of the Invention

The present invention relates generally to an electronic circuitry, and more particularly, to a sub-threshold voltage circuit of multi-channel length.

2. Description of the Related Art

When a digital circuit works at a sub-threshold voltage area, a special relationship of reverse short-channel effect (RSCE) is available between transistor threshold voltage V_{T} and transistor channel length L. The RSCE indicates that the transistor threshold voltage V_{T} lowers to increase drain current I_{D} on the contrary when the channel is prolonged. Such phenomenon happens because the channel of the transistor can eliminate drain-induced barrier lowering (DIBL) by non-uniform doping and decrease leakage current—so-called halo doping close to source/drain. In the conventional integrated circuit (IC) design, each of the logic gates includes the minimum channel length (Lₘᵢₙ), which is allowed by manufacturing process, to decrease the area occupied by the circuit. On the other hand, the channel width of some logic gates may have different degrees of amplification to provide different load driving capabilities. As shown in FIG. 5, the circuit 80 is designed with conventional logic gates of the minimum channel length Lₘᵢₙ allowed by the manufacturing process; each of the logic gates is provided with the minimum channel length Lₘᵢₙ, and however, each logic gate can have impulses of various intensities. If greater impulse is required, the wider transistor will be applied. For example, inverters 101-103 are logic gates having different load driving capabilities. The inverter 101 includes the impulse of one unit, the inverter 102 includes the impulse of two units, and the inverter 103 includes the impulse of three units.

FIG. 6 illustrates exemplary IC layout of the inverters 101-103 of three different impulses where the referral signs 201-203 indicate the IC layouts of the tree inverters 101-103 separately. Provided the manufacturing process allows that the minimum channel length is Lₘᵢₙ, the channel width of one-unit P-type metal oxide semiconductor (PMOS) transistor is Wₚ and the channel width of one-unit N-type metal oxide semiconductor (NMOS) is Wₙ, so the channel width Of the PMOS transistor of the inverter 202 is double Wₚ and the channel width of the PMOS transistor of the inverter 203 is tripple Wₚ. Similarly, the channel width of the NMOS transistor of the inverter 202 is double Wₙ and the channel width of the NMOS transistor of the inverter 203 is tripple Wₙ.

In the aforesaid circuit, all of the logic gates are of the minimum channel lengths in structure, so the performance is worse but the leakage current is less. However, if all of the logic gates are changed to be of maximum channel lengths, the performance can though be improved but the leakage current is increased. Besides, if all of the logic gates are of maximum channel lengths, the circuit area will need more for IC layout.

### SUMMARY OF THE INVENTION

The primary objective of the present invention is to provide a sub-threshold voltage circuit of multi-channel length, which can have good performance and low leakage current and can keep the circuit area to a certain degree for the IC layout.

The foregoing objective of the present invention is attained by the sub-threshold voltage circuit, which is formed on an IC and includes a plurality of logic gates. The logic gates are electrically connected with one another according to a predetermined manner and composed of a plurality of PMOS transistors and a plurality of NMOS transistors. The logic gates form a plurality of signal paths defining at least one key signal path and a plurality of general signal paths respectively. The channel lengths of the logic gates located on the general signal paths each are the minimum channel length of the manufacturing process of the transistor. The logic gate located on the at least one key signal path is an RSCE PMOS or NMOS transistor, the channel length of which is larger than the minimum channel length of the manufacturing process of the transistor to define a maximum channel length.

### BRIEF DESCRIPTION OF THE DRAWINGS

FIG. 1 is a circuit diagram of a first preferred embodiment of the present invention, illustrating the connection status of the logic gates.

FIG. 2 is a layout of the IC in accordance with the first preferred embodiment of the present invention, illustrating the channel length.

FIG. 3 is a circuit diagram of a second preferred embodiment of the present invention, illustrating the connection status of the logic gates.

FIG. 4 is a layout of the IC of the second preferred embodiment of the present invention.

FIG. 5 is a circuit diagram of the conventional sub-threshold voltage circuit, illustrating the connection status of the logic gates.

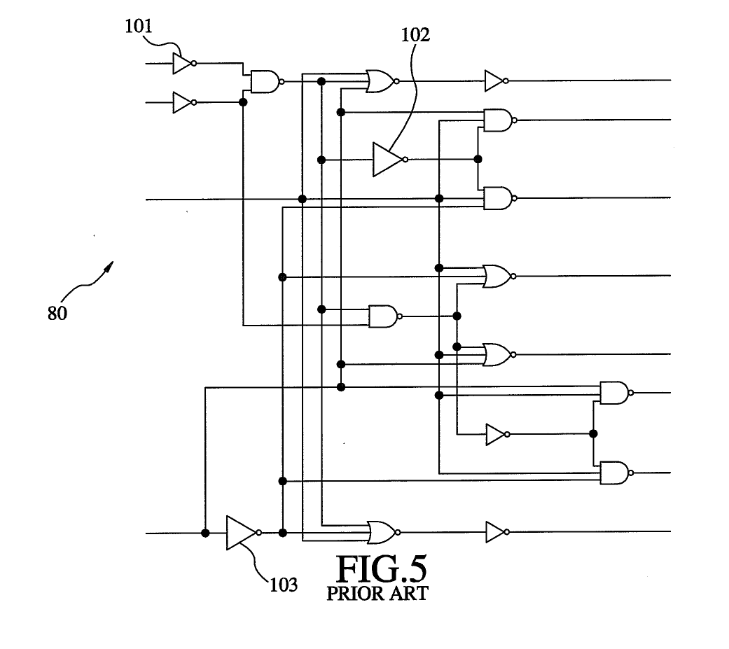

FIG. 6 is a layout of the IC of the conventional sub-threshold voltage circuit, illustrating the channel length.

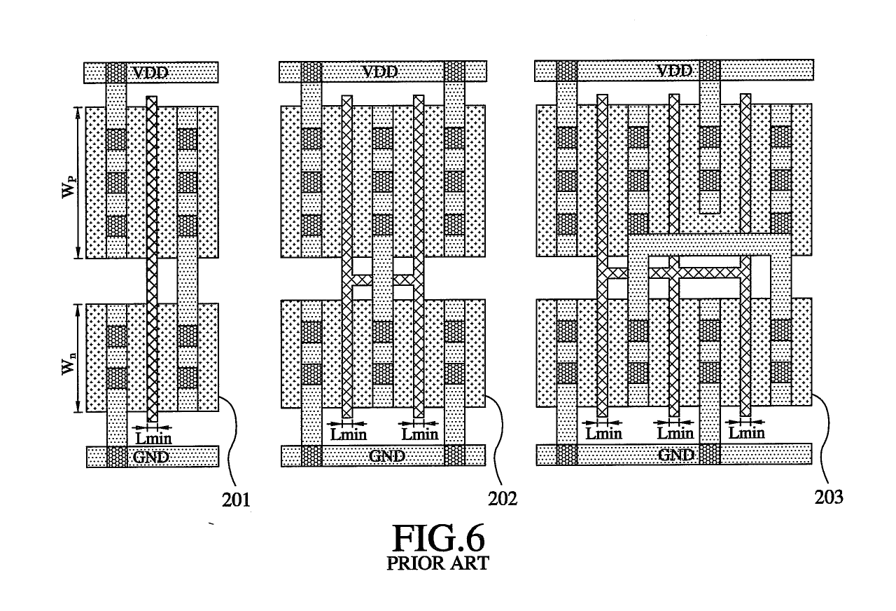

### DETAILED DESCRIPTION OF PREFERRED EMBODIMENTS

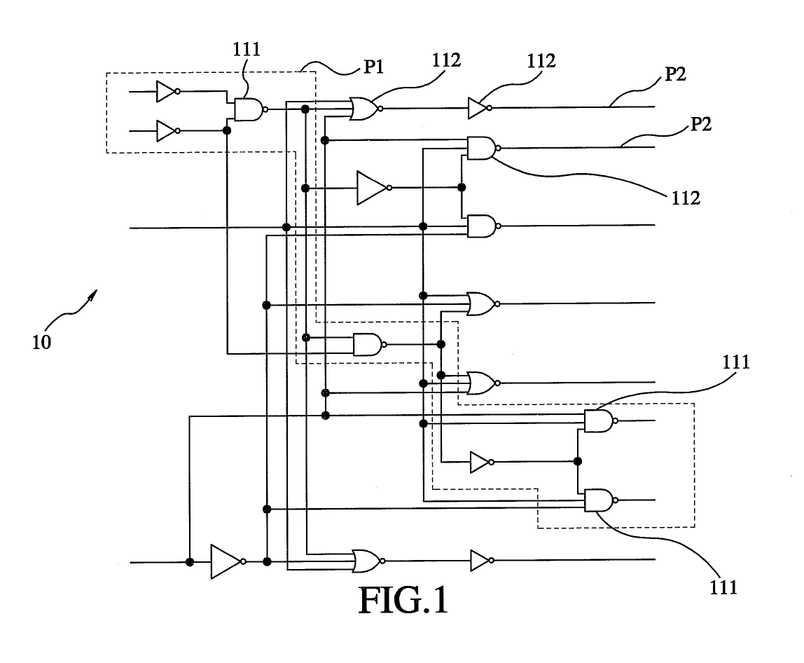

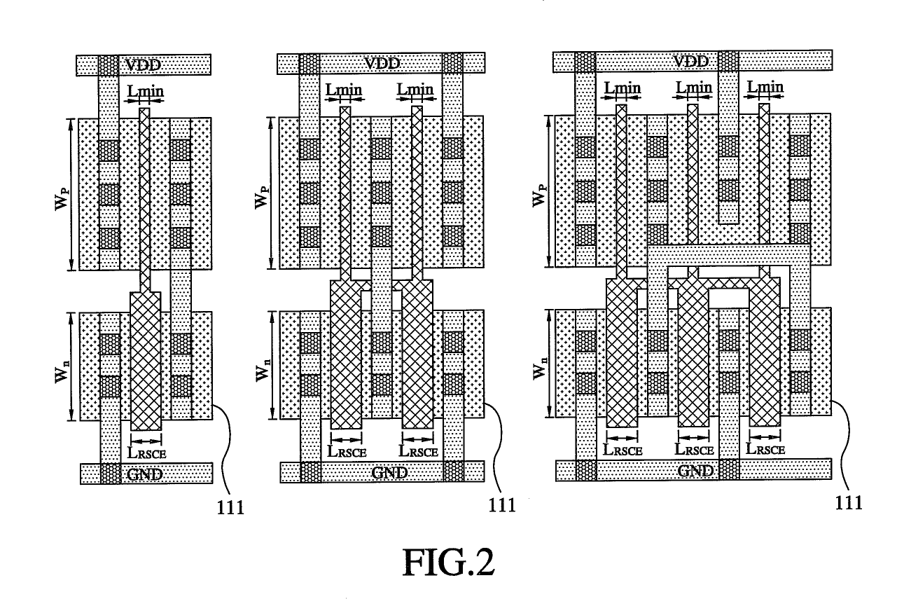

Referring to FIGS. 1-2, a sub-threshold voltage circuit 10 of multi-channel length is formed on an IC and includes a plurality of logic gates 111 and 112, which are electrically connected with one another by a predetermined manner and composed of a plurality of PMOS transistors and a plurality of NMOS transistors. The detailed descriptions and operations of these elements as well as their interrelations are recited in the respective paragraphs as follows.

The logic gates 111 and 112 form a plurality of signal paths, which are defined as at least one key signal path P1 and a plurality of general signal paths P2 according to the characteristic or requirement of the solid IC. The at least one key signal path P1 indicates the signal path in need of more impulses and in this embodiment, there is only one key signal path P1 as an example for illustration. The channel length of each logic gate 112 located on the general signal path P2 is a minimum channel length Lₘᵢₙ of the manufacturing process of the transistor. The logic gates 111 located on the key signal path P1 are RSCE PMOS or NMOS transistors, each having the channel length being larger than the minimum channel length Lₘᵢₙ to define a maximum channel length L_{RSCE}.

Referring to FIGS. 1-2, among the signal paths P1 and P, the signal paths P1 need more impulses, so the logic gates 111 on the key signal path P1 are of the maximum channel length L_{RSCE}, which are NMOS as an example in the drawings. When the impulses become more at work, the circuit performance can be improved. The logic gates 112 on the general signal paths P2 does not need more impulses, so the logic gates of the minimum channel length Lₘᵢₙ can satisfy the requirement for the impulse. Although it may happen that leakage current become more, the circuit area becomes larger, and power consumption becomes more on the key signal path, such drawbacks only happen on a part of the key signal path rather than the whole key signal path. As for the general signal paths P2, they do not have the logic gates of the maximum channel lengths L_{RSCE} thereon, so the aforesaid drawbacks will not happen on the general signal paths P2.

As can be seen from the above, the sub-threshold voltage circuit 10 of the first embodiment of the present invention can improve the circuit performance and effectively control circuit area, leakage current, and power consumption to further improve the drawbacks of the prior art.

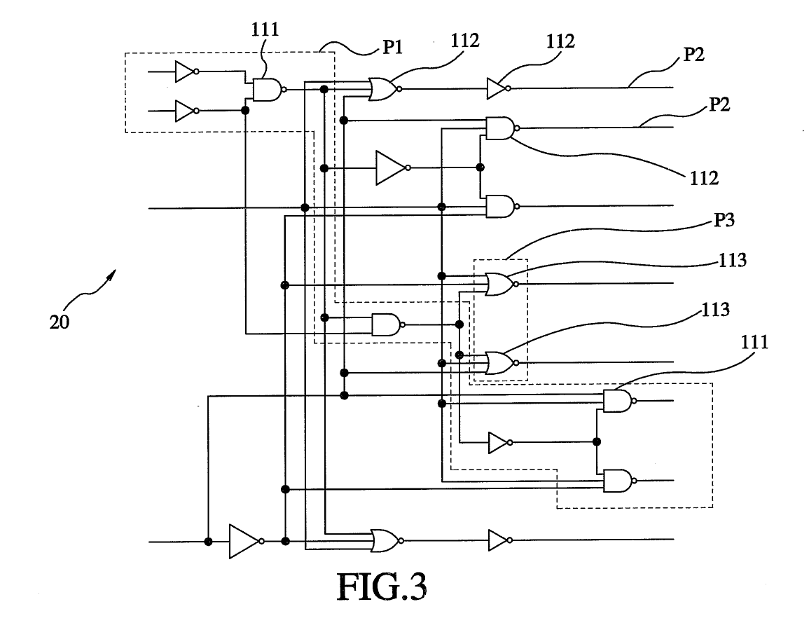

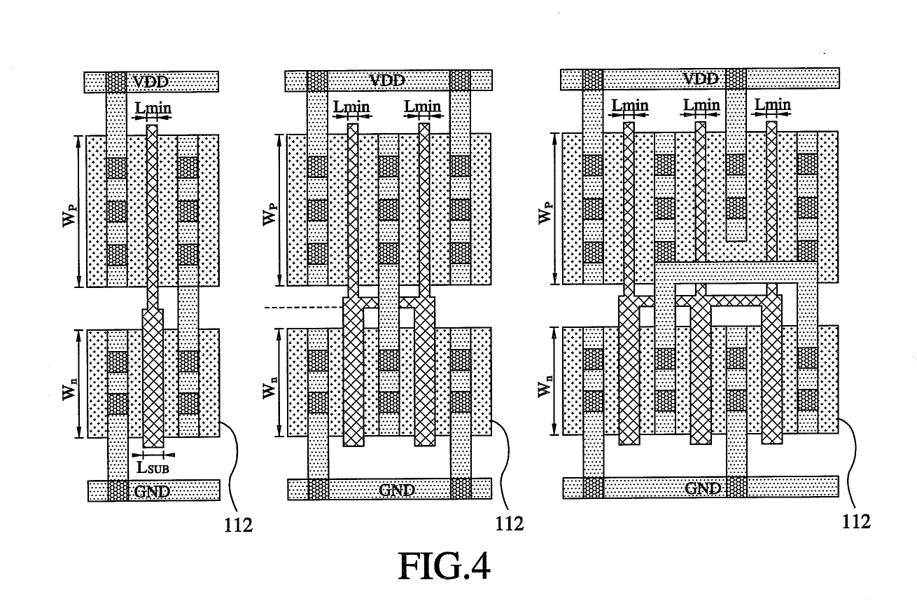

Referring to FIGS. 3-4, a sub-threshold voltage circuit 20 of multi-channel length in accordance with a second preferred embodiment of the present invention is similar to that of the first embodiment, having the following difference.

The signal paths P1-P3 define at least one key signal path P1, a plurality of general signal paths P2, and at least one sub-key signal path P3.

The channel length of each logic gate 113 located on the at least one sub-key signal path P3 is between the minimum channel length Lₘᵢₙ and the maximum channel length L_{RSCE} to define a sub-channel length L_{sub}.

The sub-channel length L_{sub} of the logic gate 113 on the at least one sub-key signal path P3 is larger than the minimum channel length Lₘᵢₙ, so the logic gates 113 can reach the circuit characteristic which is superior to that of the logic gates 112 of the minimum channel length Lₘᵢₙ. Because the sub-channel length L_{sub} of the logic gate 113 is smaller than the maximum channel lengths L_{RSCE}, so the circuit area, the leakage current, and the power consumption of the logic gates 113 are smaller than those of the logic gates 111. In this way, the circuit designer can optionally choose from the logic gates of different channel lengths to meet his or her design requirement to enable the circuit characteristic, the circuit area, the leakage current, and the power consumption to reach the optimum.

The other elements and reachable effects of the second embodiment are identical to those of the first embodiment, so further recitation is skipped.

It is to be additionally noted that FIG. 1 to which the first embodiment corresponds and FIG. 3 to which the second embodiment correspond are to illustrate the various signal paths and not to limit the two embodiments to the circuitries shown in the two drawings; other circuitries may have the signal paths subject to the actual circumstances and thus are not always identical to the circuitries of the two embodiments.

In light of the above, the present invention can be optionally provided with the logic gates of proper channel length as per the actual requirement to have the advantages of good performance of circuit characteristic, less leakage current, and keeping the circuit area to a proper degree in the IC layout.

Although the present invention has been described with respect to the specific preferred embodiments thereof, it is in no way limited to the specifics of the illustrated structures but changes and modifications may be made within the scope of the appended claims.

What is claimed is:

1. A sub-threshold voltage circuit of multi-channel length being formed on an IC, comprising:
a plurality of logic gates electrically connected with one another and having a plurality of PMOS transistors and a plurality of NMOS transistors;
the sub-threshold voltage circuit being characterized in that the logic gates form a plurality of signal paths, which define at least one key signal path and a plurality of general signal paths, the channel length of each of the logic gates located on the general signal paths being a minimum channel length of the manufacturing process of transistor, the logic gates located on the at least one key signal path being PMOS or NMOS transistors and each having a channel length larger than the minimum channel length to define a maximum channel length.

2. The sub-threshold voltage circuit as defined in claim 1, wherein the signal paths further defines at least one sub-key signal path, the channel length of each of the logic gates located on the at least one sub-key signal path being between the minimum channel length and the maximum channel length to define a sub-channel length.

3. The sub-threshold voltage circuit as defined in claim 1, wherein the at least one key signal path indicates the signal path in need of more impulses.
